(19) United States
(12) Patent Application Publication
(10) Pub. No.: US 2023/0175119 A1
(43) Pub. Date: Jun. 8, 2023

(54) PRECURSOR FOR FORMING THIN FILM, METHOD OF PREPARING THE SAME, AND METHOD OF MANUFACTURING THIN FILM INCLUDING THE SAME

(71) Applicant: SOULBRAIN CO., LTD., Gyeonggi-do (KR)

(72) Inventors: Chang Bong YEON, Gyeonggi-do (KR); Jae Sun JUNG, Gyeonggi-do (KR); Hye Ran BYUN, Gyeonggi-do (KR); Tae Young EOM, Gyeonggi-do (KR); Seok Jong LEE, Gyeonggi-do (KR)

(21) Appl. No.: 18/011,146

(22) PCT Filed: Jun. 22, 2021
(86) PCT No.: PCT/KR2021/007831

§ 371 Date: Dec. 16, 2022

(30) Foreign Application Priority Data
Jun. 24, 2020 (KR) 10-2020-0077334

(51) Int. Cl. C23C 16/18; C23C 16/455; C23C 16/34; C23C 16/40

(52) U.S. Cl. CPC C23C 16/18; C23C 16/45553; C23C 16/34; C23C 16/405

(57) ABSTRACT

The present invention relates to a precursor for forming a thin film. The precursor is in a liquid state under conditions of 20° C. and 1 bar and includes 20 to 100% by weight of a coordination compound represented by Chemical Formula 1 below and 0 to 80% by weight of an alkyl cyanide containing an alkyl group having 1 to 15 carbon atoms: [Chemical Formula 1] MXnLmYz. M is niobium, tungsten, or molybdenum; X is a halogen element; n is 1 to 6; L is an alkyl cyanide containing an alkyl group having 1 to 15 carbon atoms, or a linear or cyclic saturated hydrocarbon having 3 to 15 carbon atoms and substituted with one or more nitrogen, oxygen, phosphorus, or sulfur atoms; m is 1 to 3; bonded Y is an amine; z is an integer from 0 to 4; and n+z is 3 to 6.

### TECHNICAL FIELD

The present invention relates to a precursor for forming a thin film, a method of preparing the same, and a method of manufacturing a thin film including the same. More particularly, the present invention relates to a precursor for thin film formation that exists in a liquid state at room temperature, has a very high deposition rate due to high volatility, is easy to handle when injected into a thin film deposition chamber, and has high purity and excellent step coverage due to excellent thermal stability; a method of preparing the precursor; and a method of manufacturing a thin film including the precursor.

### BACKGROUND ART

As thin film deposition techniques such as chemical vapor deposition (CVD) and atomic layer deposition (ALD) are used, the size of semiconductor devices becomes smaller, and the degree of integration of semiconductor devices is remarkably increased.

However, in the case of chemical vapor deposition, it is difficult to form a film having a desired composition ratio or physical properties because all raw materials necessary for thin film formation are simultaneously introduced into a deposition chamber. In addition, since deposition is performed at a high temperature, deterioration of a semiconductor device or decrease in capacitance may occur.

In addition, in the case of atomic layer deposition, since raw materials necessary for thin film formation are independently supplied, a thin film having a desired composition ratio and physical properties may be formed. However, the types of precursors for thin film formation are limited. In particular, when a metal chloride is used as a precursor for forming a thin film, a dielectric film may be damaged, resulting in deterioration of leakage current.

A niobium oxide (Nb₂O₅) thin film has a high dielectric constant, is a component of ferroelectric materials, and is used as a key material constituting a high-density non-volatile memory. A niobium nitride (NbN) thin film provides a high work function even in miniaturized patterns of semiconductor devices, and thus is widely used in the semiconductor field.

In general, an Nb(OR)₅ (R is alkyl) type material is used as a precursor for forming a niobium thin film. However, the precursor for thin film formation has disadvantages such as high viscosity and low hydrolysis resistance. In addition, since an alkoxide ligand is easily dissociated, a side reaction in which oligomers or polymers are generated by heat occurs. As a result, due to decrease in volatility, disadvantages such as a low thin film formation rate and a change in the composition of a thin film may occur.

In addition, a precursor for thin film formation in the form of Nb(NMe₂)₅ has also been developed. This material has relatively good sublimation properties. However, since the material exists in a solid form, the material has low volatility compared to liquid precursors for thin film formation, and is easily decomposed at a temperature of 150° C. or higher, showing poor thermal stability. In addition, the material has poor hydrolysis resistance.

Therefore, it is necessary to develop a precursor capable of preparing a niobium thin film that exists in a liquid state at room temperature and has high volatility, excellent thermal stability, a high thin film formation rate, and excellent physical properties.

### RELATED ART DOCUMENTS

### Patent Documents

KR 2001-0038063 A

### DISCLOSURE

### Technical Problem

Therefore, the present invention has been made in view of the above problems, and it is one object of the present invention to provide a precursor for thin film formation that exists in a liquid state at room temperature, has a very high deposition rate due to high volatility, is easy to handle when injected into a thin film deposition chamber, and has high purity and excellent step coverage due to excellent thermal stability; a method of preparing the precursor; and a method of manufacturing a thin film including the precursor.

The above and other objects can be accomplished by the present invention described below.

### Technical Solution

In accordance with one aspect of the present invention, provided is a precursor for forming a thin film, wherein the precursor is in a liquid state under conditions of 20° C. and 1 bar and includes 20 to 100% by weight of a coordination compound represented by Chemical Formula 1 below and 0 to 80% by weight of an alkyl cyanide containing an alkyl group having 1 to 15 carbon atoms:

MXnLmYz [Chemical Formula 1]

wherein M is niobium (Nb), tungsten (W), or molybdenum (Mo); X is a halogen element; n is an integer from 1 to 6; L is an alkyl cyanide containing an alkyl group having 1 to 15 carbon atoms, or a linear or cyclic saturated hydrocarbon having 3 to 15 carbon atoms and substituted with one or more nitrogen (N), oxygen (O), phosphorus (P), or sulfur (S) atoms; m is an integer from 1 to 3; Y is an amine; z is an integer from 0 to 4; and n+z is an integer from 3 to 6.

In accordance with another aspect of the present invention, provided is a method of preparing a precursor for forming a thin film, the method including synthesizing a coordination compound represented by Chemical Formula 1 by reacting a compound represented by Chemical Formula 2 below with an alkyl cyanide containing an alkyl group having 1 to 15 carbon atoms or a linear or cyclic saturated hydrocarbon having 3 to 15 carbon atoms and substituted with one or more nitrogen (N), oxygen (O), phosphorus (P), or sulfur (S) atoms in an organic solvent:

MXₐY₍₆₋ₐ₎ [Chemical Formula 2]

wherein M is niobium (Nb), tungsten (W), or molybdenum (Mo); X is a halogen element; Y is an amine; and a is an integer from 1 to 6.

In accordance with yet another aspect of the present invention, provided is a method of manufacturing a thin film, the method including injecting the precursor for forming a thin film according to the present invention into a CVD chamber or an ALD chamber and adsorbing the precursor onto a surface of a loaded substrate; purging the residual unadsorbed precursor using a purge gas; supplying a reactive gas to react with the precursor adsorbed on the surface of the substrate to form a metal thin film layer; and purging reaction by-products using a purge gas.

### Advantageous Effects

According to the present invention, the present invention has an effect of providing a precursor for thin film formation that exists in a liquid state at room temperature, has a very high deposition rate due to high volatility, is easy to handle when injected into a thin film deposition chamber, and has high purity and excellent step coverage due to excellent thermal stability; a method of preparing the precursor; and a method of manufacturing a thin film including the precursor.

### DESCRIPTION OF DRAWINGS

FIG. 1 is a flowchart for explaining an ALD process according to one embodiment of the present invention.

FIG. 2 includes images taken before and after drying a precursor for forming a thin film prepared in Example 1 of the present invention.

FIG. 3 is a graph showing the results of DSC analysis of a precursor for forming a thin film prepared in Example 1 of the present invention.

FIG. 4 is a graph showing the results of TGA analysis of a precursor for forming a thin film prepared in Example 1 of the present invention.

FIG. 5 is an NMR spectrum measured before and after leaving a precursor for forming a thin film prepared in Example 1 of the present invention at 150° C. for 1 hour.

FIG. 6 is a graph showing the results of DSC analysis of a precursor for forming a thin film prepared in Example 2 of the present invention.

FIG. 7 is a graph showing the results of TGA analysis of a precursor for forming a thin film prepared in Example 2 of the present invention.

FIG. 8 is an NMR spectrum measured before and after leaving a precursor for forming a thin film prepared in Example 2 of the present invention at 150° C. for 1 hour.

### BEST MODE

Hereinafter, a precursor for forming a thin film, a method of preparing the same, and a method of manufacturing a thin film including the same according to the present invention will be described in detail.

The present inventors confirmed that, when coordinating a niobium metal or the like with a predetermined ligand, the coordination metal compound was in a liquid state at room temperature or was easily liquefied by a predetermined solvent.

In addition, the present inventors confirmed that, when the coordination metal compound was used as a precursor for forming a thin film to form a metal thin film, a thin film that exists in a liquid state at room temperature, has a very high deposition rate due to high volatility, is easy to handle when injected into a thin film deposition chamber, and has high purity and excellent step coverage due to excellent thermal stability was manufactured. Based on these results, the present inventors conducted further studies to complete the present invention.

The precursor for forming a thin film of the present invention is in a liquid state under conditions of 20° C. and 1 bar and includes 20 to 100% by weight of a coordination compound represented by Chemical Formula 1 below and 0 to 80% by weight of an alkyl cyanide containing an alkyl group having 1 to 15 carbon atoms:

MXnLmYz [Chemical Formula 1]

Here, M is niobium (Nb), tungsten (W), or molybdenum (Mo); X is a halogen element; n is an integer from 1 to 6; L is an alkyl cyanide containing an alkyl group having 1 to 15 carbon atoms, or a linear or cyclic saturated hydrocarbon having 3 to 15 carbon atoms and substituted with one or more nitrogen (N), oxygen (O), phosphorus (P), or sulfur (S) atoms; m is an integer from 1 to 3; bonded Y is an amine; z is an integer from 0 to 4; and n+z is an integer from 3 to 6. When a metal thin film is prepared using the precursor for forming a thin film, since the precursor exists in a liquid state at room temperature and is easily volatilized, the precursor has a very high deposition rate. In addition, since viscosity or vapor pressure may be easily adjusted, handling of the precursor is easy when injected into a thin film deposition chamber. In particular, since the precursor has excellent thermal stability, the precursor is not easily decomposed and has high purity, and a thin film having excellent step coverage may be manufactured.

As another example, in Chemical Formula 1, n is an integer from 2 to 4, m is an integer from 1 to 3, z is an integer from 1 to 3, and n+m+z is 6.

In the coordination compound, X is preferably fluorine, n is preferably 5, and m may be 1. In this case, the precursor exists in a liquid state at room temperature and has high volatility and excellent thermal stability. Thus, the precursor has a high deposition rate and is easy to handle. In addition, a thin film having high purity and excellent step coverage may be manufactured.

In the coordination compound, L is preferably an alkyl cyanide containing an alkyl group having 1 to 5 carbon atoms, more preferably an alkyl cyanide containing an alkyl group having 3 to 5 carbon atoms. Within this range, liquefaction may be facilitated.

As another example, in the coordination compound, L is preferably a linear or cyclic saturated hydrocarbon having 3 to 10 carbon atoms and substituted with one or more nitrogen (N) or oxygen (O) atoms, more preferably a linear or cyclic saturated hydrocarbon having 4 to 8 carbon atoms and substituted with one or more nitrogen (N) or oxygen (O) atoms, as a specific example, diethyl ether or tetrahydrofuran. Within this range, liquefaction of the precursor for forming a thin film may be facilitated.

In the present disclosure, substituting a saturated hydrocarbon with one or more nitrogen (N), oxygen (O), phosphorus (P), or sulfur (S) elements means that one or more nitrogen (N), oxygen (O), phosphorus (P), or sulfur (S) elements are intercalated between atoms of a saturated hydrocarbon or that hydrogen atoms, carbon atoms, CH groups, or CH2 groups in a saturated hydrocarbon are substituted with one or more nitrogen (N), oxygen (O), phosphorus (P), or sulfur (S) elements.

L preferably acts as a ligand.

In the coordination compound, Y is preferably a secondary amine, more preferably dialkylamine, and as a specific example, includes one or more selected from the group consisting of diethylamine, dimethylamine, ethylmethylamine, and dipropylamine. In this case, liquefaction may be facilitated.

As a preferred example, the coordination compound may be preferably a compound represented by Chemical Formula 1A below, more preferably a compound represented by Chemical Formula 1B. In this case, When a metal thin film is prepared using the precursor for forming a thin film, since the precursor exists in a liquid state at room temperature and is easily volatilized, the precursor has a very high deposition rate. In addition, since viscosity or vapor pressure may be easily adjusted, handling of the precursor is easy when injected into a thin film deposition chamber. In particular, since the precursor has excellent thermal stability, the precursor is not easily decomposed and has high purity, and a thin film having excellent step coverage may be manufactured.

MXnLmYz [Chemical Formula 1A]

In Chemical Formula 1A, M is niobium (Nb), tungsten (W), or molybdenum (Mo); X is a halogen element; n is an integer from 1 to 6; L is an alkyl cyanide containing an alkyl group having 1 to 15 carbon atoms; m is an integer from 1 to 3; Y is an amine; z is an integer from 0 to 4; and n+m+z is 6.

MXnLm [Chemical Formula 1B]

In Chemical Formula 1B, M is niobium (Nb), tungsten (W), or molybdenum (Mo); X is a halogen element; n is an integer from 3 to 6; L is an alkyl cyanide containing an alkyl group having 1 to 15 carbon atoms; m is an integer from 1 to 3; and n+m is 6.

As another example, n may an integer from 3 to 5.

The precursor for forming a thin film has a final temperature (Tf) of preferably 180° C. or higher, more preferably 180 to 250° C., still more preferably 190 to 230° C. as measured using a thermogravimetric analyzer (TGA). Within this range, due to high purity, step coverage may be excellent.

The precursor for forming a thin film has a residue of preferably less than 3% by weight, more preferably 2% by weight or less, still more preferably less than 2% by weight, most preferably 1% by weight or less as measured using a thermogravimetric analyzer (TGA). Within this range, thermal stability may be excellent.

The precursor for forming a thin film has an exothermic temperature of preferably 150° C. or higher, more preferably 150 to 230° C., still more preferably 160 to 210° C. as measured using a differential scanning calorimeter (DSC). Within this range, thermal stability may be excellent.

A method of preparing a precursor for forming a thin film according to the present invention includes a step of synthesizing a coordination compound represented by Chemical Formula 1 below by reacting a compound represented by Chemical Formula 2 below with an alkyl cyanide containing an alkyl group having 1 to 15 carbon atoms or a linear or cyclic saturated hydrocarbon having 3 to 15 carbon atoms and substituted with one or more nitrogen (N), oxygen (O), phosphorus (P), or sulfur (S) atoms in an organic solvent. In this case, a precursor for thin film formation that exists in a liquid state at room temperature, has a very high deposition rate due to high volatility, is easy to handle when injected into a thin film deposition chamber, and has high purity and excellent step coverage due to excellent thermal stability may be prepared.

MXnLmYz [Chemical Formula 1]

In Chemical Formula 1, M is niobium (Nb), tungsten (W), or molybdenum (Mo); X is a halogen element; n is an integer from 1 to 6; L is an alkyl cyanide containing an alkyl group having 1 to 15 carbon atoms, or a linear or cyclic saturated hydrocarbon having 3 to 15 carbon atoms and substituted with one or more nitrogen (N), oxygen (O), phosphorus (P), or sulfur (S) atoms; m is an integer from 1 to 3; bonded Y is an amine; z is an integer from 0 to 4; and n+z is an integer from 3 to 6.

MXₐY₍₆₋ₐ₎ [Chemical Formula 2]

In Chemical Formula 2, M is niobium (Nb), tungsten (W), or molybdenum (Mo); X is a halogen element; Y is an amine; and a is an integer from 1 to 6.

Since the description of the precursor for forming a thin film of the present invention is equally applied to the method of preparing the precursor, repeated description is omitted.

The organic solvent may be preferably a halogenated hydrocarbon, more preferably an alkyl halide containing an alkyl group having 1 to 5 carbon atoms, still more preferably a methyl halide. In this case, synthesis of the precursor for forming a thin film may proceed stably.

Based on 100% by weight in total of the compound represented by Chemical Formula 2; and the alkyl cyanide or the saturated hydrocarbon, the alkyl cyanide or the saturated hydrocarbon may be included in an amount of preferably 20 to 40% by weight, more preferably 25 to 40% by weight, still more preferably 25 to 33% by weight. Within this range, liquefaction of the precursor for forming a thin film may be facilitated.

As another example, based on the compound represented by Chemical Formula 2, the alkyl cyanide or the saturated hydrocarbon may be included in 1 to 1.5 equivalents (eq.), more preferably 1.0 to 1.2 equivalents (eq.), still more preferably 1.0 to 1.1 equivalents (eq.). Within this range, liquefaction of the precursor for forming a thin film may be facilitated.

The synthesizing is performed preferably at 15 to 25° C., more preferably at 20 to 25° C., still more preferably at 20 to 23° C. Within this range, synthesis of the precursor for forming a thin film may proceed stably.

For example, the synthesizing may be performed for 30 minutes or more, preferably 1 hour or more, as another example, 10 hours or less, preferably 5 hours or less, more preferably 2 hours or less. Within this range, synthesis of the precursor for forming a thin film may proceed stably.

The method of preparing a precursor for forming a thin film may preferably include a step of filtering the synthesized solution and a step of obtaining the coordination compound represented by Chemical Formula 1 by evaporating, under reduced pressure, a filtrate obtained after the filtration. In this case, liquefaction of the precursor for forming a thin film may be facilitated.

The evaporating under reduced pressure may be performed preferably at 80 to 150° C. and 0.1 to 100 torr, more preferably at 100 to 150° C. and 0.5 to 10 torr, still more preferably at 110 to 130° C. and 0.5 to 5 torr. Within this range, liquefaction of the precursor for forming a thin film may be facilitated.

The method of preparing a precursor for forming a thin film may preferably further include a step of mixing and diluting the obtained coordination compound with an alkyl cyanide containing an alkyl group having 1 to 15 carbon atoms. In this case, liquefaction of the precursor for forming a thin film may be facilitated.

A method of manufacturing a thin film of the present invention includes a step of injecting the precursor for forming a thin film according to the present invention into a CVD chamber or an ALD chamber to adsorb the precursor onto the surface of a loaded substrate; a step of purging the residual unadsorbed precursor using a purge gas; a step of supplying a reactive gas to react with the precursor adsorbed on the surface of the substrate to form a metal thin film layer; and a step of purging reaction by-products using a purge gas. In this case, the deposition rate of the precursor for forming a thin film may be greatly increased, handling of the precursor may be easy, and a thin film having excellent step coverage may be manufactured.

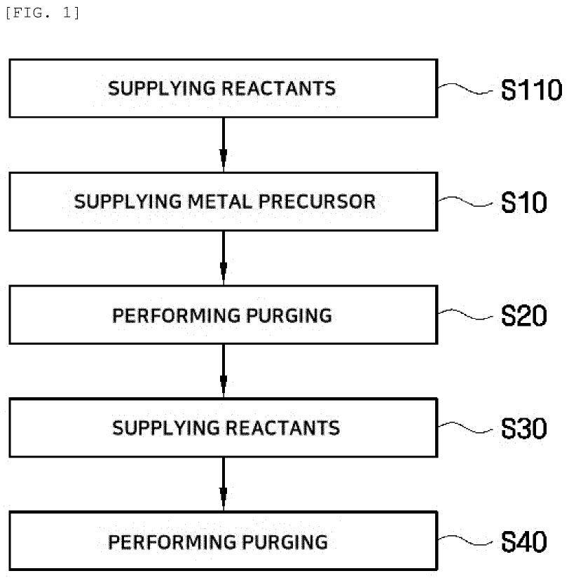

As a specific example, the method of manufacturing a thin film may follow the process sequence shown in FIG. 1 below, but the present invention is not limited thereto.

For example, the precursor for forming a thin film may be mixed with a non-polar solvent and introduced into a chamber to adjust viscosity or vapor pressure.

The substrate may be preferably a dielectric film. In this case, capacitance (Cs) of a finally manufactured capacitor may be excellent.

For example, the dielectric film may be formed of a high dielectric constant material, preferably HfO₂, Al₂O₃, TiO₂, ZrO₂, Ta₂O₅, or Y₂O₃, more preferably HfO₂.

The non-polar solvent may include preferably one or more selected from the group consisting of alkanes and cycloalkanes. In this case, step coverage may be improved even when deposition temperature is increased when forming a thin film while containing an organic solvent having low reactivity and solubility and easy water management.

As a more preferred example, the non-polar solvent may include a C1 to C10 alkane or a C3 to C10 cycloalkane, preferably a C3 to C10 cycloalkane. In this case, reactivity and solubility may be reduced, and moisture management may be easy.

In the present disclosure, C1, C3, and the like mean the carbon number.

The cycloalkane may be preferably a C3 to C10 monocycloalkane. Among the monocycloalkanes, cyclopentane exists in a liquid state at room temperature and has the highest vapor pressure, and thus is preferable in a vapor deposition process. However, the present invention is not limited thereto.

For example, the non-polar solvent has a solubility (25° C.) of 200 mg/L or less, preferably 50 to 200 mg/L, more preferably 135 to 175 mg/L in water. Within this range, reactivity to the precursor for forming a thin film may be low, and moisture management may be easy.

In the present disclosure, solubility may be measured without particular limitation according to measurement methods or standards commonly used in the art to which the present invention pertains. For example, solubility may be measured according to the HPLC method using a saturated solution.

Based on a total weight of the precursor for forming a thin film and the non-polar solvent, the non-polar solvent may be included in an amount of preferably 5 to 95% by weight, more preferably 10 to 90% by weight, still more preferably 40 to 90% by weight, most preferably 70 to 90% by weight.

When the content of the non-polar solvent exceeds the above range, impurities are generated to increase resistance and impurity levels in a thin film. When the content of the non-polar solvent is less than the above range, an effect of improving step coverage and reducing an impurity such as chlorine (Cl) ion due to addition of the solvent may be reduced.

For example, in the method of manufacturing a thin film, the rate of decrease in thin film growth rate per cycle (A/Cycle) calculated by Equation 1 below is −5% or less, preferably −10% or less, more preferably −20% or less, still more preferably −30% or less, still more preferably −40% or less, most preferably −45% or less. Within this range, step coverage and the thickness uniformity of the film may be excellent.

Rate of decrease in thin film growth rate per cycle (%)=[(Thin film growth rate per cycle when a growth inhibitor for thin film formation is used−Thin film growth rate per cycle when no growth inhibitor for thin film formation is used)/Thin film growth rate per cycle when no growth inhibitor for thin film formation is used]×100 [Equation 1]

In the method of manufacturing a thin film, residual halogen intensity (c/s) in a thin film formed after 200 cycles, measured based on SIMS, may be preferably 10,000 or less, more preferably 8,000 or less, still more preferably 7,000 or less, still more preferably 6,000 or less. Within this range, the effect of preventing corrosion and deterioration may be excellent.

In the present disclosure, purging may be performed preferably at 1,000 to 10,000 sccm, more preferably at 2,000 to 7,000 sccm, still more preferably at 2,500 to 6,000 sccm. Within this range, a thin film growth rate per cycle may be reduced to a desirable range, and process by-products may be reduced.

The atomic layer deposition process (ALD) is very advantageous in fabricating integrated circuits (ICs) requiring a high aspect ratio, and in particular, due to a self-limiting thin film growth mechanism, excellent conformality and uniformity and precise thickness control may be achieved.

For example, in the method of manufacturing a thin film, the deposition temperature may be 50 to 900° C., preferably 300 to 700° C., more preferably 350 to 600° C., still more preferably 400 to 550° C., still more preferably 400 to 500° C. Within this range, an effect of growing a thin film having excellent film quality may be obtained while implementing ALD process characteristics.

For example, in the method of manufacturing a thin film, the deposition pressure may be 0.1 to 10 torr, preferably 0.5 to 5 torr, most preferably 1 to 3 torr. Within this range, a thin film having a uniform thickness may be obtained.

In the present disclosure, the deposition temperature and the deposition pressure may be temperature and pressure in a deposition chamber or temperature and pressure applied to a substrate in a deposition chamber.

The method of manufacturing a thin film may preferably include a step of increasing temperature in a chamber to a deposition temperature before introducing the precursor for forming a thin film into the chamber; and/or a step of performing purging by injecting an inert gas into the chamber before introducing the precursor for forming a thin film into the chamber.

As a specific example, the method of manufacturing a thin film is described in detail as follows.

First, a substrate on which a thin film is to be formed is placed in a deposition chamber capable of performing atomic layer deposition.

The substrate may include a semiconductor substrate such as a silicon substrate or a silicon oxide substrate.

A conductive layer or an insulating layer may be further formed on the substrate.

To deposit a thin film on the substrate placed in the deposition chamber, a precursor for forming a thin film or a mixture of the precursor and a non-polar solvent is prepared.

Thereafter, the prepared precursor or mixture of the precursor and the non-polar solvent is injected into a vaporizer, converted into a vapor phase, transferred to a deposition chamber, and adsorbed on the substrate. Then, the non-adsorbed composition for thin film formation is purged.

In the present disclosure, for example, when the precursor for forming a thin film is transferred to the deposition chamber, a vapor flow control (VFC) method using a mass flow control (MFC) method, or a liquid delivery system (LDS) using a liquid mass flow control (LMFC) method may be used. Preferably, the LDS method is used.

At this time, one selected from argon (Ar), nitrogen (N₂), and helium (He) or a mixed gas of two or more thereof may be used as a transport gas or a diluent gas for moving the precursor for forming a thin film on the substrate, but the present invention is not limited thereto.

In the present disclosure, for example, an inert gas may be used as the purge gas, and the transport gas or the dilution gas may be preferably used as the purge gas.

Next, a reactive gas is supplied. Reactive gases commonly used in the art to which the present invention pertains may be used as the reactive gas of the present invention without particular limitation. Preferably, the reactive gas may include a reducing agent, a nitrifying agent, or an oxidizing agent. A metal thin film is formed by reacting the reducing agent with the precursor for thin film formation adsorbed on the substrate, a metal nitride thin film is formed by the nitrifying agent, and a metal oxide thin film is formed by the oxidizing agent.

Preferably, the reducing agent may be an ammonia gas (NH₃) or a hydrogen gas (H₂), the nitrifying agent may be a nitrogen gas (N₂), and the oxidizing agent may include one or more selected from the group consisting of H₂O, H₂O₂, O₂, O₃, and N₂O.

Next, the unreacted residual reactive gas is purged using an inert gas. Accordingly, in addition to the excess reactive gas, produced by-products may also be removed.

As described above, the step of adsorbing a precursor for forming a thin film on a substrate, the step of purging the unadsorbed composition for forming a thin film, the step of supplying a reactive gas, and the step of purging the remaining reactive gas may be set as a unit cycle. The unit cycle may be repeatedly performed to form a thin film having a desired thickness.

For example, the unit cycle may be performed 100 to 1,000 times, preferably 100 to 500 times, more preferably 150 to 300 times. Within this range, desired thin film properties may be effectively expressed.

The semiconductor substrate of the present invention is manufactured using the method of manufacturing a thin film according to the present invention. In this case, corrosion or deterioration may be prevented, step coverage may be excellent, and thickness uniformity of the thin film may be greatly improved.

The semiconductor substrate may preferably be a thin film capacitor or a semiconductor device capacitor.

Preferably, the manufactured thin film has a thickness of 20 nm or less, a resistivity value of 0.1 to 400 μΩ·cm, a halogen content of 10,000 ppm or less, and a step coverage of 90% or more. Within this range, the thin film has excellent performance as a diffusion barrier and may reduce corrosion of metal wiring materials, but the present invention is not limited thereto.

For example, the thin film may have a thickness of 5 to 20 nm, preferably 10 to 20 nm, more preferably 15 to 18.5 nm, still more preferably 17 to 18.5 nm. Within this range, thin film properties may be excellent.

For example, the thin film may have a resistivity value of 0.1 to 400 μΩ·cm, preferably 50 to 400 μΩ·cm, more preferably 200 to 400 μΩ·cm, still more preferably 300 to 400 μΩ·cm, still more preferably 330 to 380 μΩ·cm, most preferably 340 to 370 μΩ·cm. Within this range, thin film properties may be excellent.

The thin film may have a halogen content of preferably 9,000 ppm or less or 1 to 9,000 ppm, more preferably 8,500 ppm or less or 100 to 8,500 ppm, still more preferably 8,200 ppm or less or 1,000 to 8,200 ppm. Within this range, thin film properties may be excellent, and corrosion of metal wiring materials may be reduced.

For example, the thin film may have a step coverage of 80% or more, preferably 90% or more, more preferably 93% or more. Within this range, even a thin film with a complex structure may be easily deposited on a substrate. Thus, the thin film may be applied to next-generation semiconductor devices.

For example, the manufactured thin film may be an NbN thin film or an NbO₂ thin film, preferably an NbN thin film.

Hereinafter, the present invention will be described in more detail with reference to the following preferred examples and drawings. However, these examples and drawings are provided for illustrative purposes only and should not be construed as limiting the scope and spirit of the present invention. In addition, it will be apparent to those skilled in the art that various changes and modifications may be made without departing from the spirit and scope of the present invention, and such changes and modifications are also within the scope of the appended claims.

### Examples

<Synthesis of Precursor for Forming Thin Film>

### Example 1 (Preparation of Niobium Coordination Compound Coordinated with 2-methylbutyronitrile)

In a glove box, 137 g (0.73 mol, 1 equivalent) of niobium fluoride (V) as a starting material was placed in a 3 L flask. The starting material was diluted with 0.5 M dichloromethane (1.5 L) as a solvent. 74 mL (0.73 mol, 1 equivalent) of 2-methylbutylronitrile, which was a ligand to be coordinated, was injected therein, followed by stirring at room temperature for 1 hour and filtration. After removing the solvent from the obtained filtrate by distillation under reduced pressure, a desired precursor was obtained in a colorless liquid (158 g) with a yield of 80% through a purification process (70° C. @ 1.0 torr).

### Example 2 (Preparation of Niobium Coordination Compound Coordinated with 2,2-dimethylvaleronitrile)

In a glove box, 126 g (0.67 mol, 1 equivalent) of niobium fluoride (V) as a starting material was placed in a 3 L flask. The starting material was diluted with 0.5 M dichloromethane (1.4 L) as a solvent. 92 mL (0.67 mol, 1 equivalent) of 2,2-dimethylvaleronitrile, which was a ligand to be coordinated, was injected therein, followed by stirring at room temperature for 1 hour and filtration. After removing the solvent from the obtained filtrate by distillation under reduced pressure, a desired precursor was obtained in a colorless liquid (160 g) with a yield of 80% through a purification process (70° C. @ 1.0 torr).

### Experimental Examples

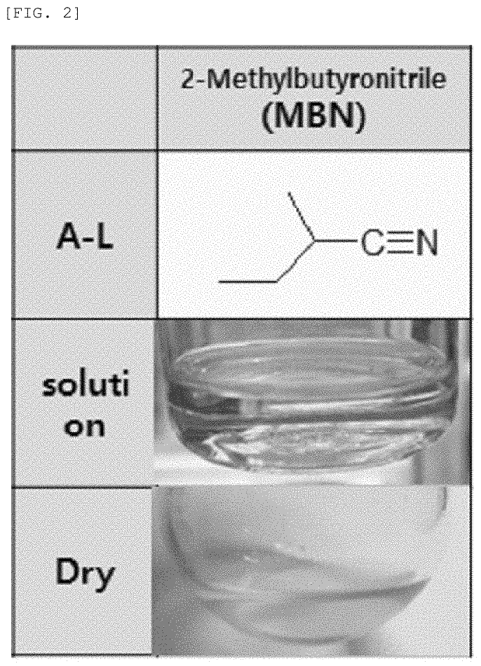

Dry state evaluation, DSC analysis, TGA analysis, and NMR analysis of the precursors for thin film formation prepared in Examples 1 and 2 were performed, and the results are shown in FIGS. 2 to 8 below.

FIG. 2 below includes images taken before and after drying the precursor for forming a thin film prepared in Example 1. Even after drying (Dry), that is, even when the alkyl cyanide as a solvent was not included, the precursor was still in a liquid state as before drying (solution).

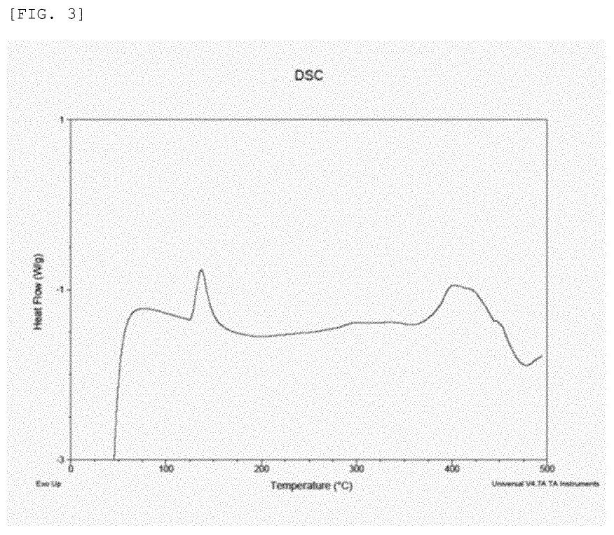

FIG. 3 below is a graph showing the results of DSC analysis of the precursor for forming a thin film prepared in Example 1. The precursor has an exothermic temperature of 150° C., exists in a liquid state at room temperature, has a very high deposition rate due to high volatility thereof, and is easy to handle when injected into a thin film deposition chamber. In particular, since the precursor has excellent thermal stability, it can be expected that a thin film having high purity and excellent step coverage may be manufactured by using the precursor.

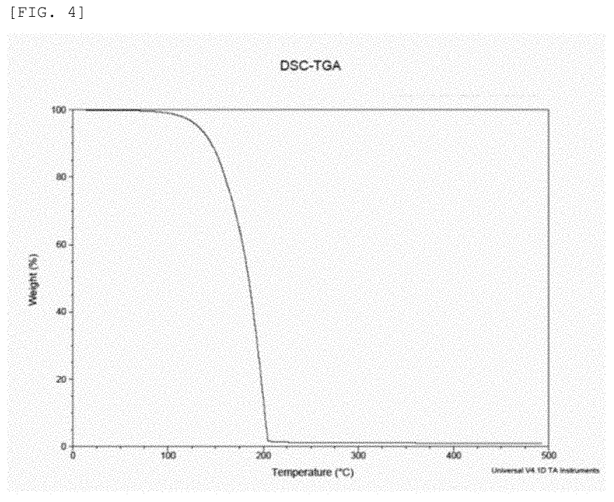

FIG. 4 below is a graph showing the results of TGA analysis of the precursor for forming a thin film prepared in Example 1. It was confirmed that the precursor had a final temperature (To) of 200° C., had a residue of less than 3% by weight, and had high thermal stability and high purity. Of note, if the thermal stability of the precursor for thin film formation was reduced and the coordinated ligand was separated from the niobium metal, a 2-pattern would be observed. However, the precursor for thin film formation according to the present invention prepared in Example 1 exhibited a 1-pattern step-like graph, suggesting that the precursor was not thermally decomposed at all.

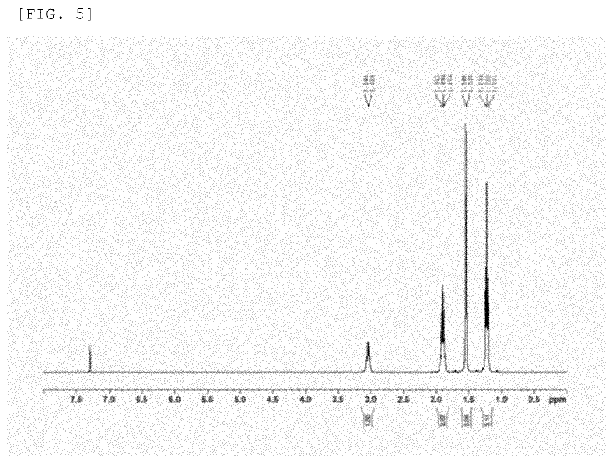

FIG. 5 shows the NMR spectrum of the precursor for forming a thin film prepared in Example 1. From this result, it was confirmed that a desired niobium-coordinated compound coordinated with 2-methylbutyronitrile was prepared.

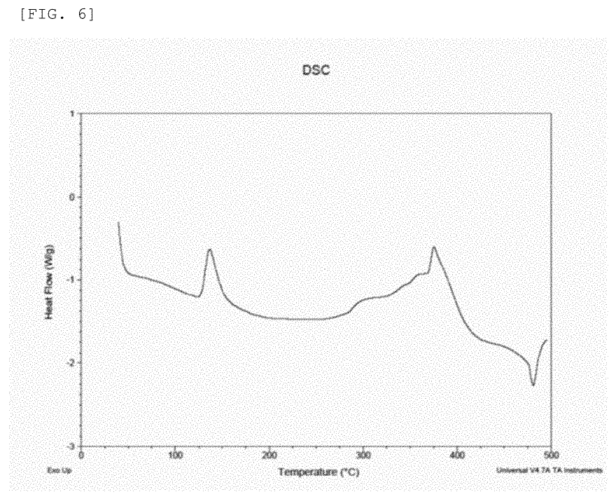

FIG. 6 below is a graph showing the results of DSC analysis of the precursor for forming a thin film prepared in Example 2. The precursor has an exothermic temperature of 150° C., exists in a liquid state at room temperature, has a very high deposition rate due to high volatility thereof, and is easy to handle when injected into a thin film deposition chamber. In particular, since the precursor has excellent thermal stability, it can be expected that a thin film having high purity and excellent step coverage may be manufactured by using the precursor.

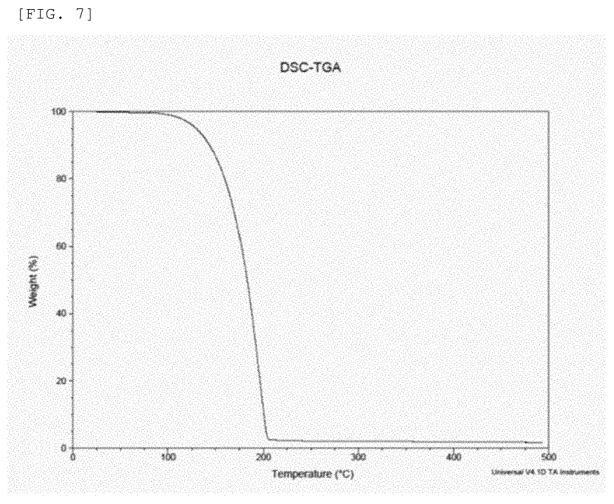

FIG. 7 below is a graph showing the results of TGA analysis of the precursor for forming a thin film prepared in Example 2. The precursor had a final temperature (To) of 200° C., had a residue of less than 3% by weight, and had high thermal stability and high purity. Thus, it was confirmed that the precursor was suitable for manufacturing a high-quality thin film.

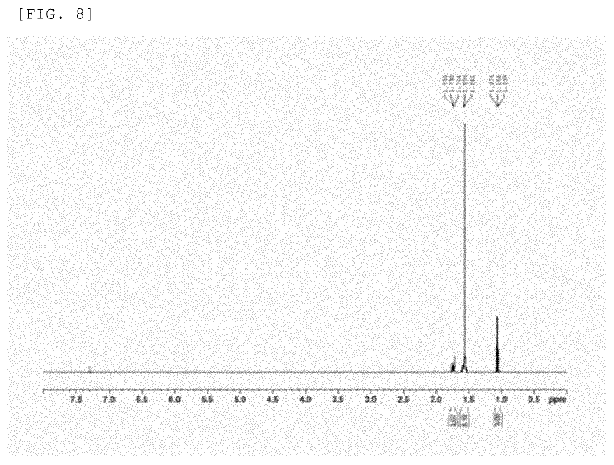

FIG. 8 below is the NMR spectrum of the precursor for forming a thin film prepared in Example 2. From this result, it was confirmed that a desired niobium coordination compound coordinated with 2,2-dimethylvaleronitrile was prepared.

In conclusion, when the precursor for forming a thin film according to the present invention is used, a thin film that exists in a liquid state at room temperature, has a very high deposition rate due to high volatility, is easy to handle when injected into a thin film deposition chamber, and has high purity and excellent step coverage due to excellent thermal stability may be manufactured.

1. A precursor for forming a thin film, wherein the precursor is in a liquid state under conditions of 20° C. and 1 bar and comprises 20 to 100% by weight of a coordination compound represented by Chemical Formula 1 below and 0 to 80% by weight of an alkyl cyanide containing an alkyl group having 1 to 15 carbon atoms:
MXnLmYz [Chemical Formula 1]
wherein M is niobium (Nb), tungsten (W), or molybdenum (Mo); X is a halogen element; n is an integer from 1 to 6; L is an alkyl cyanide containing an alkyl group having 1 to 15 carbon atoms, or a linear or cyclic saturated hydrocarbon having 3 to 15 carbon atoms and substituted with one or more nitrogen (N), oxygen (O), phosphorus (P), or sulfur (S) atoms; m is an integer from 1 to 3; Y is an amine; z is an integer from 0 to 4; and n+z is an integer from 3 to 6.

2. The precursor according to claim 1, wherein, in the coordination compound, X is fluorine, n is 5, and m is 1.

3. The precursor according to claim 1, wherein, in the coordination compound, L is an alkyl cyanide containing an alkyl group having 1 to 5 carbon atoms.

4. The precursor according to claim 1, wherein the precursor for forming a thin film has a final temperature (Tf) of 180° C. or higher as measured using a thermogravimetric analyzer (TGA).

5. The precursor according to claim 1, wherein the precursor for forming a thin film has a residue of less than 3% by weight as measured using a thermogravimetric analyzer (TGA).

6. The precursor according to claim 1, wherein the precursor for forming a thin film has an exothermic temperature of 150° C. or higher as measured using a differential scanning calorimeter (DSC).

7. A method of preparing a precursor for forming a thin film, comprising synthesizing a coordination compound represented by Chemical Formula 1 below by reacting a compound represented by Chemical Formula 2 below with an alkyl cyanide containing an alkyl group having 1 to 15 carbon atoms or a linear or cyclic saturated hydrocarbon having 3 to 15 carbon atoms and substituted with one or more nitrogen (N), oxygen (O), phosphorus (P), or sulfur (S) atoms in an organic solvent:
MXnLmYz [Chemical Formula 1]
wherein M is niobium (Nb), tungsten (W), or molybdenum (Mo); X is a halogen element; n is an integer from 1 to 6; L is an alkyl cyanide containing an alkyl group having 1 to 15 carbon atoms, or a linear or cyclic saturated hydrocarbon having 3 to 15 carbon atoms and substituted with one or more nitrogen (N), oxygen (O), phosphorus (P), or sulfur (S) atoms; m is an integer from 1 to 3; Y is an amine; z is an integer from 0 to 4; and n+z is an integer from 3 to 6,
MXaY(6-a) [Chemical Formula 2]
wherein M is niobium (Nb), tungsten (W), or molybdenum (Mo); X is a halogen element; Y is an amine; and a is an integer from 1 to 6.

8. The method according to claim 7, wherein the organic solvent is a halogenated hydrocarbon.

9. The method according to claim 7, wherein the alkyl cyanide or the saturated hydrocarbon is comprised in an amount of 20 to 40% by weight based on 100% by weight in total of the compound represented by Chemical Formula 2 and the alkyl cyanide or the saturated hydrocarbon.

10. The method according to claim 7, wherein the synthesizing is performed at 15 to 25° C.

11. The method according to claim 7, comprising filtering the synthesized solution; and obtaining the coordination compound represented by Chemical Formula 1 by evaporating under reduced pressure a filtrate obtained after the filtration.

12. The method according to claim 11, further comprising diluting the obtained coordination compound with an alkyl cyanide containing an alkyl group having 1 to 15 carbon atoms.

13. A method of manufacturing a thin film, comprising:
adsorbing the precursor for forming a thin film according to claim 1 onto a surface of a loaded substrate by injecting the precursor into a CVD chamber or an ALD chamber,
purging the unadsorbed residual precursor using a purge gas,
forming a thin metal film layer by supplying a reactive gas to react with the precursor adsorbed on the surface of the substrate, and
purging reaction by-products using a purge gas.

14. The method according to claim 13, wherein the reactive gas is a reducing agent, a nitrifying agent, or an oxidizing agent.

15. The method according to claim 13, wherein the precursor for forming a thin film is transferred to the substrate surface by a VFC method, a DLI method, or an LDS method.
